(19) United States
(12) Patent Application Publication
(10) Pub. No.: US 2024/0315082 A1
(43) Pub. Date: Sep. 19, 2024

(54) ORGANIC LIGHT-EMITTING DIODE DISPLAY PANEL AND METHOD OF MANUFACTURING THEREOF

(71) Applicant: Shenzhen China Star Optoelectronics Semiconductor Display Technology Co., Ltd., Shenzhen (CN)

(72) Inventors: Xiaoxing ZHANG, Shenzhen (CN); Yuanjun HSU, Shenzhen (CN)

(73) Assignee: Shenzhen China Star Optoelectronics Semiconductor Display Technology Co., Ltd., Shenzhen (CN)

(21) Appl. No.: 18/398,405

(22) Filed: Dec. 28, 2023

(30) Foreign Application Priority Data
Mar. 13, 2023 (CN) 202310272316.5

(51) Int. Cl. H10K 59/122; H10K 59/12; H10K 59/80; H10K 71/00

(52) U.S. Cl. CPC H10K 59/122; H10K 59/1201; H10K 59/80515; H10K 71/621

(57) ABSTRACT

A method of manufacturing an organic light-emitting diode (OLED) display panel includes: providing a thin film transistor (TFT) substrate comprising a first surface; forming a planarization layer on the first surface; forming an anode layer on a surface of the planarization layer away from the TFT substrate; forming a dam layer on a surface of the anode layer away from the planarization layer; removing the dam layer not shielded by a semi-transparent mask and the anode layer not covered by the dam layer to form a patterned dam layer and a patterned anode layer; and removing a part of the patterned dam layer to expose a part of the patterned anode layer.

### CROSS-REFERENCE TO RELATED APPLICATION

This application claims the benefit of priority of Chinese Patent Application No. 202310272316.5, filed on Mar. 13, 2023, the contents of which are incorporated by reference as if fully set forth herein in their entirety.

### TECHNICAL FIELD

The present disclosure relates to display technologies, and in particular, to an organic light-emitting diode (OLED) display panel and a method of manufacturing thereof.

### BACKGROUND

When manufacturing organic light-emitting diode (OLED) display panels, three processes are continuously circulated including film formation, exposure, and etching. Masks are used many times to form a pattern of an anode and a pattern of a shielding adhesive layer. Every time one mask is used, one additional process flow will be added, which may increase time cost and material cost, and may further decrease a yield of the OLED display panels.

### SUMMARY

In view of the above, the present disclosure provides an organic light-emitting diode (OLED) display panel and a method of manufacturing thereof, so as to solve a problem that time cost and material cost of manufacturing the OLED display panel are increased caused by repeated use of masks.

The technical solution adopted by the present application for solving the above technical problem is as follows:

The present disclosure provides a method of manufacturing an OLED display panel, including: providing a thin film transistor (TFT) substrate including a first surface; forming a planarization layer on the first surface; forming an anode layer on a surface of the planarization layer away from the thin film transistor substrate; forming a dam layer on a surface of the anode layer away from the planarization layer; removing the dam layer not shielded by a semi-transparent mask and the anode layer not covered by the dam layer to form a patterned dam layer and a patterned anode layer; and removing a part of the patterned dam layer to expose a part of the patterned anode layer.

The present disclosure provides an OLED display panel including a TFT substrate including a first surface, a planarization layer disposed on the first surface, an anode layer disposed on a surface of the planarization layer away from the TFT substrate and covering a part of the planarization layer, and a dam layer disposed on a surface of the anode layer away from the planarization layer and exposing a part of the anode layer.

Beneficial effects of the embodiment of the present disclosure: The present disclosure provides the OLED display panel and the method of manufacturing thereof, a part of the dam layer is shielded by the semi-transparent mask, and a part of the anode layer is shielded by the dam layer, so that the dam layer and the anode layer are patterned by using only one semi-transparent mask and one removing process. The patterned dam layer is removed to expose a part of the patterned anode layer to provide a connection surface for subsequent connection between other parts and the anode layer. The patterned anode layer is defined mainly by the dam layer disposed on the anode layer and covering a part of the anode layer. The dam layer and the anode layer are patterned by the semi-transparent mask disposed on the dam layer. A part of the dam layer and a part of the anode layer are removed, so that the anode layer and the dam layer are patterned completely. The semi-transparent mask which is equivalent to a mask plate is only used once in the whole process, which reduces use times and working procedures of the mask plate, improves operation efficiency, reduces operation cost, and reduces the risk that a yield of the display panel due to repeated use of the mask plate.

### BRIEF DESCRIPTION OF THE DRAWINGS

To describe the technical solutions of the embodiments of the present disclosure more clearly, the following briefly introduces the accompanying drawings used in the description of the embodiments of the present disclosure. Apparently, the accompanying drawings described below illustrate only some exemplary embodiments of the present disclosure, and are not limiting thereto.

FIG. 1 is a schematic flowchart of a method of manufacturing an organic light-emitting diode display panel in the prior art.

FIG. 2 is a schematic diagram of a process of manufacturing the organic light-emitting diode display panel in the prior art.

FIG. 3 is a schematic flowchart of a method of manufacturing an organic light-emitting diode display panel according to an embodiment of the present disclosure.

FIG. 4 is a schematic structural diagram of the organic light-emitting diode display panel according to an embodiment of the present disclosure.

FIG. 5 is a schematic diagram of a process of manufacturing the organic light-emitting diode display panel according to an embodiment of the present disclosure.

### DETAILED DESCRIPTION

The technical solutions in the embodiments of the present disclosure will be described clearly and completely hereafter with reference to the accompanying drawings. Apparently, the described embodiments are only a part of but not all embodiments of the present disclosure. All other embodiments obtained by persons of ordinary skill in the art based on the embodiments of the present disclosure without creative efforts shall fall within the protection scope of the present disclosure.

In the present disclosure, terms such as “first” and “second” are used herein for purposes of description, and should not be interpreted as an indication or implication of relative importance, or implied indication of a number of the technical features. Therefore, features limited by terms such as “first” and “second” can explicitly or impliedly include one or more than one of these features. In description of the disclosure, “a plurality of” means two or more than two, unless otherwise specified.

In the present disclosure, the term “exemplary” is used to mean “serving as an example, illustration, or illustration”. Any embodiment described in the present disclosure, as “exemplary” is not necessarily construed as being more preferred or advantageous than other embodiments. The following description is given to enable any person skilled in the art to practice and use the present disclosure, In the following description, details are set forth for purposes of explanation. It should be understood that those skilled in the art will recognize that the present disclosure may be practiced without the use of these specific details. In other examples, known structures and processes will not be elaborated in detail to avoid unnecessary details that obscure the description of the present disclosure. Therefore, the present disclosure is not intended to be limited to the embodiments shown, but is consistent with the widest scope consistent with the principles disclosed herein.

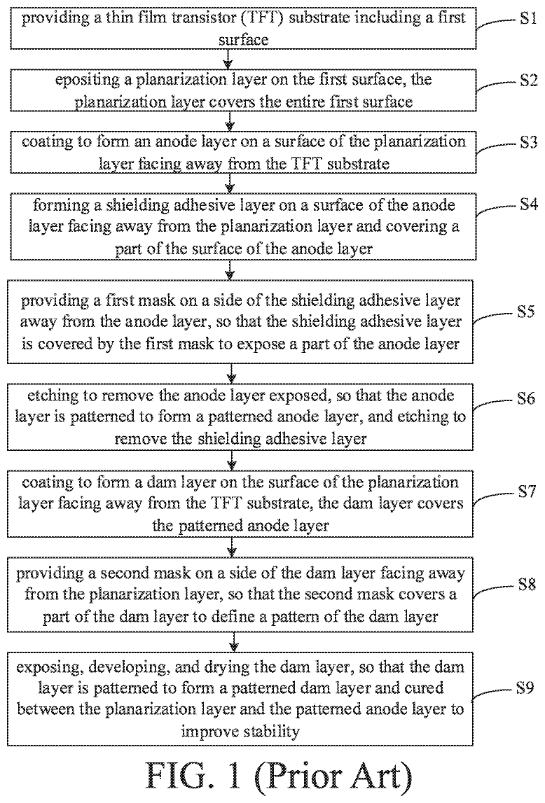

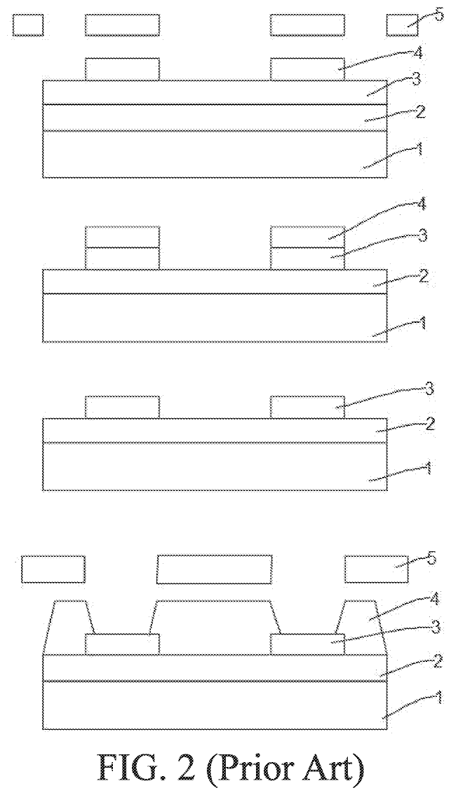

One process of manufacturing an organic light-emitting diode (OLED) display panel is to pattern an anode layer and expose the anode layer subsequent connection with other devices. At present, this process is mainly completed by continuously cycling three processes including film formation, exposure, and etching. In order to understand differences between the technical solution provided by this present disclosure and the prior art, please refer to FIG. 1 and FIG. 2, a method of manufacturing an OLED display panel in the prior art is briefly introduced as follows.

The method of manufacturing the OLED display panel in the prior art includes:
Step S1, providing a thin film transistor (TFT) substrate 1 including a first surface.
Step S2, depositing a planarization layer 2 on the first surface, the planarization layer 2 covers the entire first surface.
Step S3, coating to form an anode layer 3 on a surface of the planarization layer 2 facing away from the TFT substrate 1.
Step S4, forming a shielding adhesive layer on a surface of the anode layer 3 facing away from the planarization layer 2 and covering a part of the surface of the anode layer 3.
Step S5, providing a first mask on a side of the shielding adhesive layer away from the anode layer 3, so that the shielding adhesive layer is covered by the first mask to expose a part of the anode layer 3.
Step S6, etching to remove the anode layer 3 exposed, so that the anode layer 3 is patterned to form a patterned anode layer, and etching to remove the shielding adhesive layer.
Step S7, coating to form a dam layer 4 on the surface of the planarization layer 2 facing away from the TFT substrate 1, the dam layer 4 covers the patterned anode layer 3.
Step S8, providing a second mask on a side of the dam layer 4 facing away from the planarization layer 2, so that the second mask covers a part of the dam layer 4 to define a pattern of the dam layer 4.
Step S9, exposing, developing, and drying the dam layer 4, so that the dam layer 4 is patterned to form a patterned dam layer 4 and cured between the planarization layer 2 and the patterned anode layer 3 to improve stability.

The process of the display panel above needs to use at least two masks including a first mask and a second mask. The first mask is mainly used for patterning the anode layer 3, and the second mask is mainly used for patterning the dam layer 4. Since the whole process requires at least two masks and multiple etches, resulting in too many processes, thereby affecting a preparation efficiency of the display panel and further increasing cost. In addition, since the patterned dam layer 4 and the patterned anode layer 3 are formed by two different masks, molding errors may occur in the two formation processes, so that the patterned anode layer 3 and the patterned dam layer 4 do not necessarily match, thereby affecting a yield of the display panel after molding.

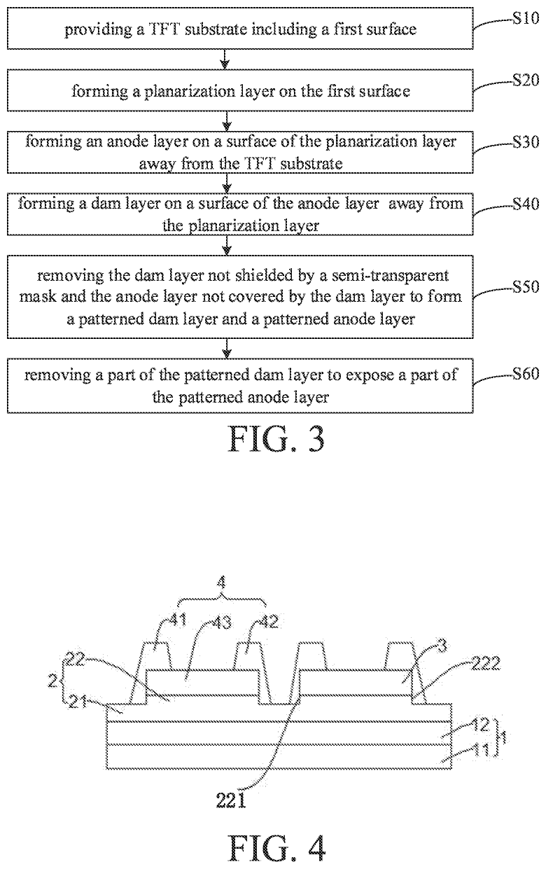

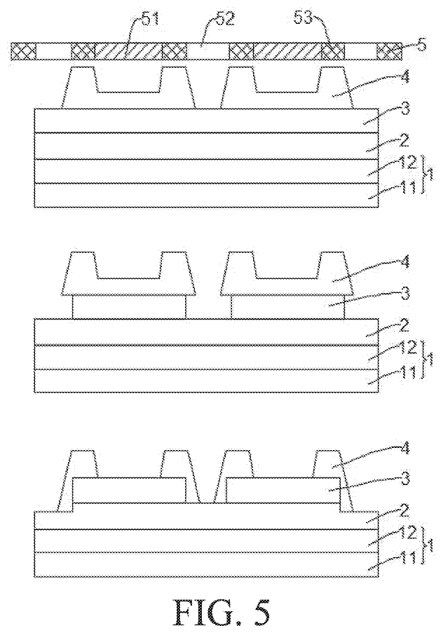

For this reason, in view of the problem existing in the method of manufacturing the display panel, please refer to FIG. 3 to FIG. 5 together, the present disclosure provides a method of manufacturing an OLED display panel, including:
Step S10, providing a TFT substrate 1 including a first surface.
Step S20, forming a planarization layer 2 on the first surface.
Step S30, forming an anode layer 3 on a surface of the planarization layer 2 away from the TFT substrate 1.
Step S40, forming a dam layer 4 on a surface of the anode layer 3 away from the planarization layer 2.
Step S50, removing the dam layer 4 not shielded by a semi-transparent mask 5 and the anode layer 3 not covered by the dam layer 4 to form a patterned dam layer 4 and a patterned anode layer 3.
Step S60, removing a part of the patterned dam layer 4 to expose a part of the patterned anode layer 3.

The technical solution provided by the present disclosure is mainly to form a dam layer 4 covering a part of the anode layer 3, and the dam layer 4 may play a role of defining a pattern of the anode layer 3. The semi-transparent mask 5 is disposed on the dam layer 4, and the dam layer 4 is patterned by using the semi-transparent mask 5. After the dam layer 4 is defined, the dam layer 4 and the anode layer 3 are simultaneously etched to remove a part of the anode layer 3 not shielded by the dam layer 4 and the semi-transparent mask 5 and a part of the dam layer 4 not shielded by the semi-transparent mask 5, thereby obtaining the patterned dam layer 4 and the patterned anode layer 3. Both the dam layer 4 and the anode layer 3 are patterned by the same semi-transparent mask 5 and the same etching process, which reduces times of using the semi-transparent mask 5, reduces the etching process, improves the manufacturing efficiency of the display panel, and reduces manufacturing cost. In addition, since both the dam layer 4 and the anode layer 3 are patterned in the same etching process by using the same semi-transparent mask 5, patterning errors between the dam layer 4 and the anode layer 3 may be reduced and the yield of the display panel may be improved. Furthermore, a part of the patterned dam layer 4 is removed, so that a part of the patterned anode layer 3 may be exposed, which is convenient for the subsequent connection between the anode layer 3 and other devices.

In some embodiments, the semi-translucent mask 5 includes a semi-translucent area 51, a fully translucent area 52, and an opaque area 53. The semi-transparent area 51 refers to an area where only a certain frequency band of light entering the area is allowed to pass through, while the remaining light is absorbed. The fully transparent area 52 refers to an area where almost all the light entering the area passes through, excluding natural light loss. The opaque area 53 refers to an area where all the light entering the area is absorbed and cannot pass through. The semi-transparent area 51 and the fully transparent area 52 are connected by the opaque area 53 to separate the semi-transparent area 51 from the fully transparent area 52, so that when the light passes through different areas, it affects the film layers to form corresponding patterns. The semi-translucent area 51 covers the dam layer 4, so that a part of the dam layer 4 covered by the semi-translucent area 51 is photoetched. The fully transparent arca 52 covers the anode layer 3 and the dam layer 4 covers the anode layer 3, so that the anode layer 3 is etched by the light passing through the fully transparent area 52. The opaque area 53 absorbs the light to protect the anode layer 3 and the dam layer 4 corresponding to the opaque area 53 from being etched. After the etching process is finished, both the dam layer 4 and the anode layer 3 are patterned. In the whole process, the dam layer 4 and the anode layer 3 are etched at the same time, and the placement of the mask twice is not involved, which may reduce the working procedure and cost, and ensure a patterning accuracy of the etching. It should further be noted that the part of the dam layer 4 is etched, an etching thickness of the part of the dam layer 4 etched cannot be too thick, and the part of the dam layer 4 needs to be retained to cover the anode layer 3 to prevent the anode layer 3 covered by the dam layer 4 from being etching away, which affects the formation of the patterns.

Furthermore, the providing a semi-transparent mask 5 on the dam layer 4, and removing the dam layer 4 not shielded by the semi-transparent mask 5 and the anode layer 3 not covered by the dam layer 4 to form the patterned dam layer 4 and the patterned anode layer 3 includes:

Providing the semi-transparent mask 5 on the dam layer 4, so that the semi-transparent area 51 covers the dam layer 4, and the fully transparent area 52 covers the anode layer 3.

Etching the anode layer 3 and the dam layer 4, so that the part of the dam layer 4 corresponding to the semi-transparent area 51 and the part of the anode layer 3 corresponding to the fully transparent area 52 are etched away to form the patterned dam layer 4 and the patterned anode layer 3, respectively.

The semi-transparent area 51 covers the dam layer 4, so that the light for etching the dam layer 4 selectively passes through the semi-transparent area 51 to etch the dam layer 4. The fully transparent area 52 covers the anode layer 3, so that the light passes through the area to etch the anode layer 3. The pattern of the dam layer 4 and the pattern of the anode layer 3 are defined through the cooperation of the dam layer 4 and the semi-transparent mask 5, and then the pattern of the dam layer 4 and the anode layer 3 is realized synchronously by etching, so as to reduce the etching process and improve the pattern accuracy.

In some embodiments, the removing the part of the patterned dam layer to expose the part of the patterned anode layer includes: removing a part of the dam layer 4 adjacent to the anode layer 3 by an ashing process, so that the dam layer 4 sinks towards the anode layer 3 to expose a part of the patterned anode layer 3; and drying the dam layer 4 and the anode layer 3 at high temperature to cure the dam layer 4 ashed.

A part of the anode layer 3 is removed by the ashing process. Specifically, a part of the dam layer 4 adjacent to the anode layer 3, that is, a part of the dam layer 4 in contact with the anode layer 3 is removed. After this part of the dam layer 4 is removed, the remaining dam layer 4 sinks towards the anode layer 3, because a bottom of the dam layer 4 is removed. A specific thickness of the dam layer 4 is removed so that the anode layer 3 may be exposed. For convenience of understanding, a structural relationship between the patterned dam layer 4 and the patterned anode layer 3 is explained in detail.

The dam layer includes a first dam 41, a second dam 42, and a connecting dam 43 for connecting the first dam 41 and the second dam 42. The first dam 41 and the second dam 42 are disposed on both sides of the anode layer 3, respectively. A width of the connecting dam 43 matches a width of the semi-transparent area 51. In the first etching of the dam layer 4, the connecting dam 43 is mainly etched. The ashing process is mainly used for removing the connecting dam 43 to expose the anode layer 3 originally covered by the connecting dam 43. The first dam 41 and the second dam 42 are also ashed by the ashing process, so that the first dam 41 and the second dam 42 may sink due to the removal of the connecting dam 43. A height of the subsidence of the first dam 41 and the second dam 42 is equal to a thickness of the connecting dam 43. After the first dam 41 and the second dam 42 have sunk, the remaining dam layer 4 is formed on the anode layer 3 and wraps the side surfaces of the anode layer 3. After that, the dam layer 4 through the ashing process is heated and cured through a high-temperature drying process, so that the connection between the dam layer 4 and the anode layer 3 can be stable.

Furthermore, in the process of removing the part of the dam layer 4 by the ashing process, a part of the planarization layer 2 not covered by the patterned anode layer 3 is removed, so that the planarization layer 2 is in a stepped shape. For ease of understanding, the planarization layer 2 in a stepped shape is defined in two layers including a first step layer 21 and a second step layer 22. The second step layer 22 is located on a surface of the first step layer 21 facing away from the TFT substrate 1. A segment difference is formed between the first step layer 21 and the second step layer 22. Both sides of the second step layer 22 are defined as a first segment difference surface 221 and a second segment difference surface 222. After covering the side surfaces of the patterned anode layer 3, the first dam 41 may extend towards the planarization layer 2 until it contacts a surface of the first step layer 21, thereby covering the first segment difference surface 221, and further ensuring that one side surface of the patterned anode layer 3 may be effectively protected. Similarly, after covering the side surfaces of the patterned anode layer 3, the second dam 42 may extend towards the planarization layer 2 until it contacts the surface of the first step layer 21, thereby covering the second segment difference surface 222, and further ensuring that the other side surface of the patterned anode layer 3 may be effectively protected.

In some embodiments, the providing the TFT substrate 1 includes: providing a substrate 11 including a second surface; and forming a TFT layer on the second surface.

The substrate 11 may be a glass substrate 11 or a flexible substrate 11, which is not limited. A specific structure of the TFT layer 12 is related to the prior art and will not be described too much.

It should be noted that in any of the above embodiments, a material of the anode layer 3 may be indium tin oxide (ITO), indium zinc oxide (IZO), aluminum (Al), and the like, which is not limited.

It should further be noted that after the anode layer 3 on the planarization layer 2 is patterned, at least one patterned anode layer 3 may be provided on the planarization layer 2. Each patterned anode layer 3 corresponds to each patterned dam layer 4.

Referring to FIG. 4, the present disclosure further provides an OLED display panel including a TFT substrate 1 including a first surface, a planarization layer 2 disposed on the first surface, an anode layer 3 disposed on a surface of the planarization layer 2 away from the TFT substrate 1 and covering a part of the planarization layer, and a dam layer 4 disposed on a surface of the anode layer 3 away from the planarization layer 2 and exposing a part of the anode layer 3. It should be noted that the anode layers 3 referred to here and later are patterned anode layers 3, and the patterned anode layers 3 may be multiple or one, which are located on the planarization layer 2.

The OLED display panel provided in this embodiment is mainly patterned by the dam layer 4 and the anode layer 3, and the dam layer 4 only covers a part of the anode layer 3, so that a part of the anode layer 3 is exposed, which is convenient for the subsequent connection between the anode layer 3 and other devices.

In some embodiments, the dam layer 4 includes a first dam 41 and a second dam 42 disposed both sides of the anode layer 3, respectively. A part of the first dam 41 is disposed on the surface of the anode layer 3 away from the planarization layer 2, and another part of the first dam 41 extends toward the planarization layer 2 to cover a side surface of the anode layer 3. Similarly, a part of the second dam 42 is disposed on the surface of the anode layer 3 away from the planarization layer 2, and another part of the second dam 42 extends toward the planarization layer 2 to cover another side surface of the anode layer 3. By providing the first dam 41 and the second dam 42, both sides of the anode layer 3 may be effectively covered to protect and isolate the anode layer 3.

Furthermore, the planarization layer 2 is in a stepped shape and includes a first step layer 21 and a second step layer 22 disposed on a surface of the first step layer 21 away from the TFT substrate 1. A segment difference is formed between the first step layer 41 and the second step layer 42, and two sides of the second step layer 42 include a first segment difference surface 221 and a second segment difference surface 222. Each patterned anode layer 3 is correspondingly located on a surface of the second step layer 22 facing away from the first step layer 21. The part of the first dam 41 extends towards the planarization layer 2 to the first step layer 21 and covers the first segment difference surface 211. The part of the second dam 42 extends toward the planarization layer 2 to the first step layer 41 and covers the second segment difference surface 222. The anode layer 3 is effectively protected by covering the first segment difference surface 211 and second segment difference surface 222 with the first dam 41 and second dam 42, respectively, so that both sides of the anode layer 3 may be completely wrapped by the first dam 41 and second dam 42, thereby effectively protecting anode layer 3.

In some embodiments, the first dam 41 and the second dam 42 are symmetrically disposed with a central axis perpendicular to the anode layer 3 as an axis of symmetry, which is beneficial for improving accuracy between the first dam 41, the second dam 42, and the anode layer 3. The first dam 41 and the second dam 42 are symmetrically disposed by simultaneously etching the anode layer 3 and the dam layer 4 with a semi-transparent mask 5, and the symmetrical formation process is relatively simple and accurate.

The basic concepts have been described above and it will be apparent to those skilled in the art that the above detailed disclosure is provided by way of example only and is not intended to limit the present disclosure. Although not explicitly stated herein various modifications improvements and modifications may be made to the present disclosure by those skilled in the art. Such modifications and modifications are proposed in the present disclosure so that such modifications remain within the spirit and scope of the exemplary embodiments of the present disclosure.

At the same time, specific terms are used to describe embodiments of the present disclosure. As “one embodiment”, “an embodiment”, and/or “some embodiment” mean a certain feature, structure, or feature relevant to at least one embodiment of that present disclosure. Therefore, it should be emphasized and noted that “an embodiment”, “an embodiment”, or “an alternative embodiment” mentioned two or more times in different places in this specification do not necessarily refer to the same embodiment. In addition, certain feature structures or features in one or more embodiments of the present disclosure may be suitably combined.

By the same token, it should be noted that in the foregoing description of the embodiments of the present disclosure, various features are sometimes incorporated into one embodiment, the drawings, or the description thereof to simplify the presentation of the disclosure herein and thereby facilitate the understanding of one or more embodiments of the disclosure. However, this disclosed method does not imply that the subject of the disclosure requires more features than are mentioned in the claims. In fact, the features of the embodiments are less than all the features of the individual embodiments disclosed above.

For each patent, patent disclosure, patent application disclosure, and other materials referenced in this present disclosure, such as articles, books, specifications, publications, documents, etc., the entire content is hereby incorporated into this present disclosure as a reference, except for application history documents that are inconsistent or conflict with the content of this present disclosure, and documents that limit the widest scope of claims in this present disclosure (currently or later attached to this present disclosure). It should be noted that if there is any inconsistency or conflict between the description, definition, and/or use of terms in the accompanying materials of this present disclosure and the content of this present disclosure, the description, definition, and/or use of terms in this application shall prevail.

What is claimed is:

1. A method of manufacturing an organic light-emitting diode (OLED) display panel, comprising:
providing a thin film transistor (TFT) substrate comprising a first surface;
forming a planarization layer on the first surface;
forming an anode layer on a surface of the planarization layer away from the TFT substrate;
forming a dam layer on a surface of the anode layer away from the planarization layer;
removing the dam layer not shielded by a semi-transparent mask and the anode layer not covered by the dam layer to form a patterned dam layer and a patterned anode layer; and
removing a part of the patterned dam layer to expose a part of the patterned anode layer.

2. The method according to claim 1, wherein the semi-transparent mask comprises a semi-transparent area, a fully transparent area, and an opaque area; the semi-transparent area covers the dam layer to pattern the dam layer, the fully transparent area covers the anode layer to pattern the anode layer, and the semi-transparent area and the fully transparent area are connected through the opaque area.

3. The method according to claim 2, wherein the removing the dam layer not shielded by the semi-transparent mask and the anode layer not covered by the dam layer to form the patterned dam layer and the patterned anode layer comprises:
providing the semi-transparent mask on the dam layer, so that the semi-transparent area covers the dam layer, and the fully transparent area covers the anode layer; and
etching the anode layer and the dam layer, so that the part of the dam layer corresponding to the semi-transparent area and the part of the anode layer corresponding to the fully transparent area are etched away to form the patterned dam layer and the patterned anode layer, respectively.

4. The method according to claim 1, wherein the removing the part of the patterned dam layer to expose the part of the patterned anode layer comprises:
removing a part of the dam layer adjacent to the anode layer by an ashing process, so that the dam layer is depressed towards the anode layer to expose a part of the patterned anode layer; and
drying the dam layer and the anode layer at high temperature to cure the dam layer ashed.

5. The method according to claim 4, wherein a part of the planarization layer not covered by the patterned anode layer is removed during the process of removing the part of the dam layer by the ashing process, so that the planarization layer is in a stepped shape.

6. The method according to claim 1, wherein the providing the TFT substrate comprises:
providing a substrate comprising a second surface; and
forming a TFT layer on the second surface.

7. An organic light-emitting diode (OLED) display panel, comprising:
a thin film transistor (TFT) substrate, comprising a first surface;
a planarization layer, disposed on the first surface;
an anode layer, disposed on a surface of the planarization layer away from the TFT substrate and covering a part of the planarization layer; and
a dam layer, disposed on a surface of the anode layer away from the planarization layer and exposing a part of the anode layer.

8. The OLED display panel according to claim 7, wherein the dam layer comprises a first dam and a second dam disposed both sides of the anode layer, respectively; a part of the first dam is disposed on the surface of the anode layer away from the planarization layer, and another part of the first dam extends toward the planarization layer to cover a side surface of the anode layer; a part of the second dam is disposed on the surface of the anode layer away from the planarization layer, and another part of the second dam extends toward the planarization layer to cover another side surface of the anode layer.

9. The OLED display panel according to claim 8, wherein the planarization layer is in a stepped shape and comprises a first step layer and a second step layer disposed on a surface of the first step layer away from the TFT substrate; a segment difference is formed between the first step layer and the second step layer, and two sides of the second step layer comprise a first segment difference surface and a second segment difference surface; the part of the first dam extends towards the planarization layer to the first step layer and covers the first segment difference surface; the part of the second dam extends toward the planarization layer to the first step layer and covers the second segment difference surface.

10. The OLED display panel according to claim 8, wherein the first dam and the second dam are symmetrically disposed with a central axis perpendicular to the anode layer as an axis of symmetry.
